(19) United States
(12) Patent Application Publication
(10) Pub. No.: US 2009/0098701 A1
(43) Pub. Date: Apr. 16, 2009

(54) Method of manufacturing an integrated circuit

(76) Inventors: Jurgen Faul, Radebeul (DE); Martin Popp, Dresden (DE); Andrew Graham, Dresden (DE); Dongping Wu, Dresden (DE); Victor Verdugo, Dresden (DE)

Correspondence Address: FAY KAPLUN & MARCIN, LLP, 150 BROADWAY, SUITE 702, NEW YORK, NY, 10038, US

(21) Appl. No.: 11/974,570

(22) Filed: Oct. 15, 2007

(51) Int. Cl. H01L 21/336

(52) U.S. Cl. 438/270; 257/E21.41

(57) ABSTRACT

The present invention provides a method of manufacturing an integrated circuit comprising the steps of: providing a semiconductor substrate, etching at least one trench into a surface of said semiconductor substrate, performing an ion implantation step, wherein a direction of said ion implantation step is parallel to a vertical centre line of said trench, and performing a single oxidation step to form a first oxide layer with a first layer thickness covering a bottom of said at least one trench and a second oxide layer with a second layer thickness covering the sidewalls of said at least one trench, wherein said first layer thickness differs from said second layer thickness.

### BACKGROUND OF THE INVENTION

An integrated circuit, like for example a DRAM, often comprises a plurality of supports and a plurality of recessed channel transistors. Sometimes, an integrated circuit even comprises a plurality of two different types of transistors. In this case, it may be advantageous or necessary to cover the first and the second plurality of support regions with oxide layers that have two different layer thicknesses.

Additionally, a recessed channel transistor often comprises a trench. The bottom and the sidewalls of such a trench are normally covered by oxide layers with different layer thicknesses.

Conventionally, the formation of the different oxide layers covering different support regions or the bottom and the sidewalls of some trenches requires at least two different oxidation steps. These different oxidation steps increase the number of process steps which are necessary to produce an integrated circuit, for instance a DRAM.

### BRIEF SUMMARY OF THE INVENTION

Aspects of the invention are listed in claims 1, 9, 18 and 24.

Further aspects are listed in the respective dependent claims.

Exemplary embodiments of the present invention are illustrated in the drawings and are explained in more detail in the description below.

### DESCRIPTION OF THE DRAWINGS

In the figures:

FIG. 1A to 1H show cross sections of a semiconductor substrate for illustrating a first embodiment of the method of manufacturing an integrated circuit; namely a) as a cross section of an array perpendicular to a wordline to be formed; b) as a cross section of said array parallel to the wordline to be formed; and c) as a cross section of a support separated from said array;

FIG. 2A to 2F show cross sections of a semiconductor substrate for illustrating a second embodiment of the method of manufacturing an integrated circuit; namely a) as a cross section of an array perpendicular to a wordline to be formed; b) as a cross section of said array parallel to the wordline to be formed; and c) as a cross section of a support separated from said array; and

FIG. 3A to 3F show cross sections of a semiconductor substrate for illustrating a third embodiment of the method of manufacturing an integrated circuit; namely a) as a cross section of an array perpendicular to a wordline to be formed; b) as a cross section of said array parallel to the wordline to be formed; and c) as a cross section of a support separated from said array.

### DESCRIPTION OF THE PREFERRED EMBODIMENTS

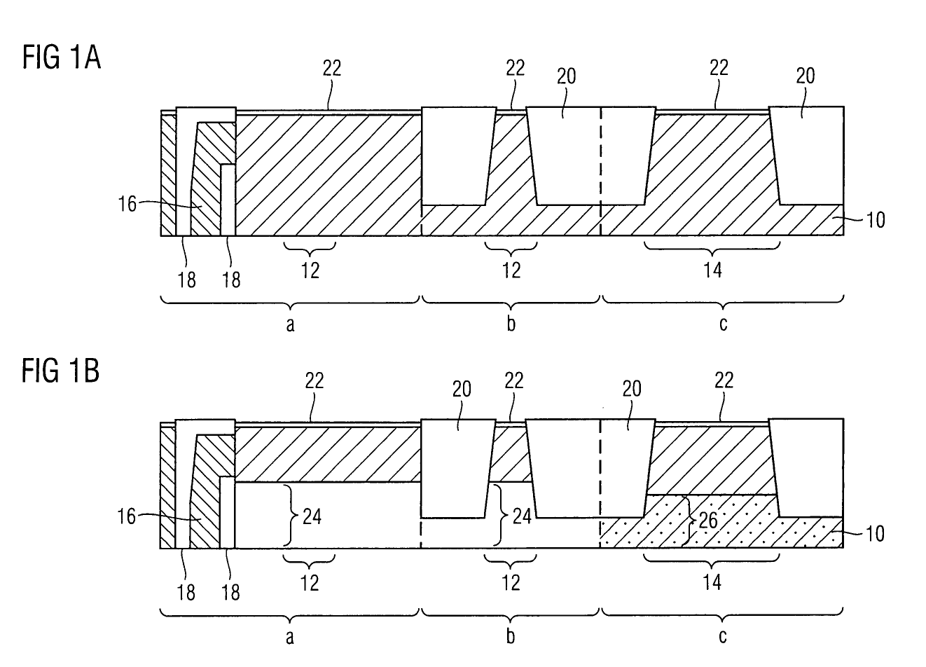

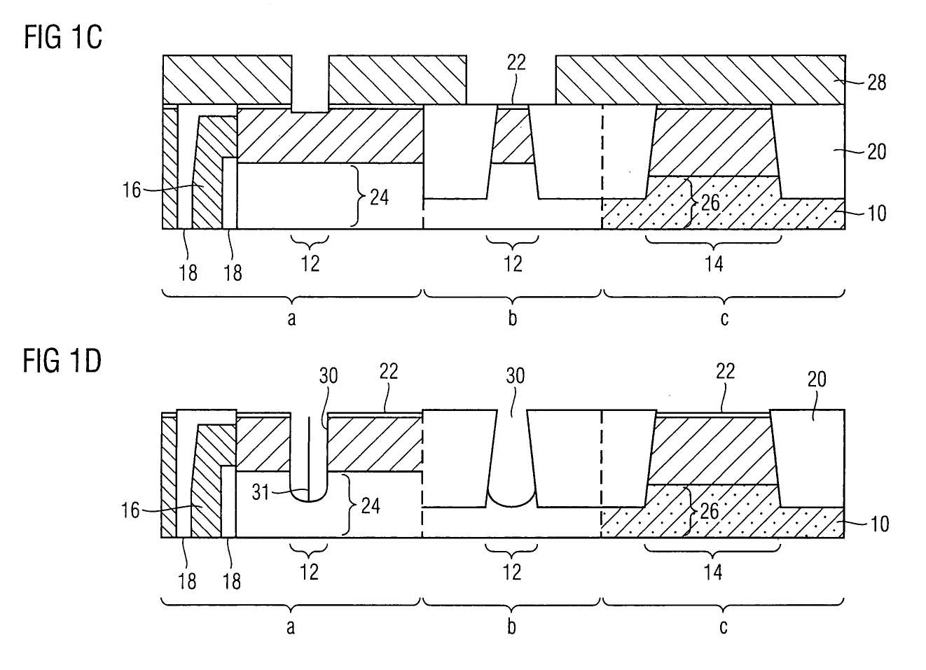

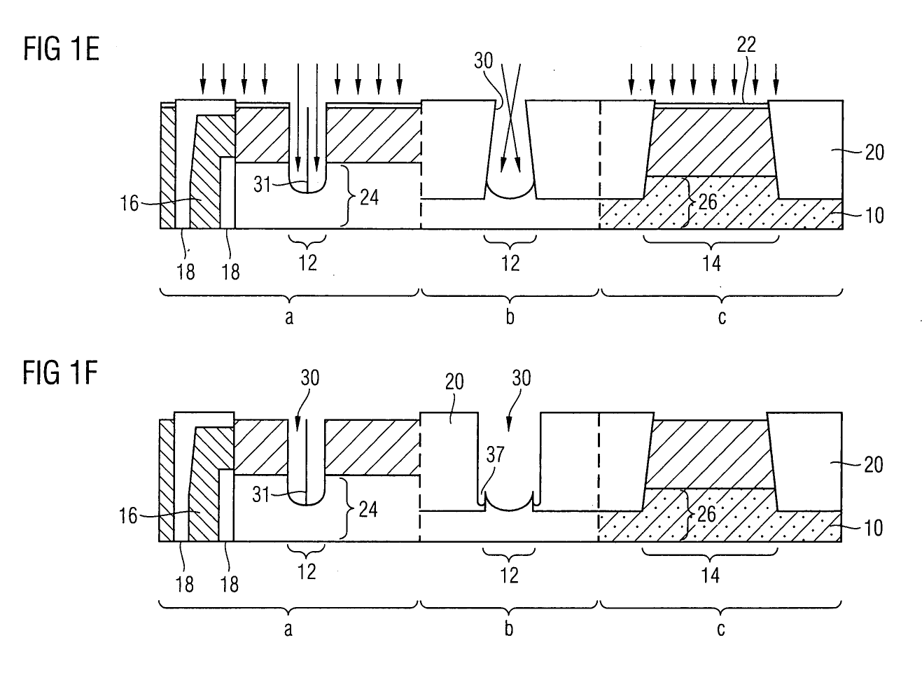

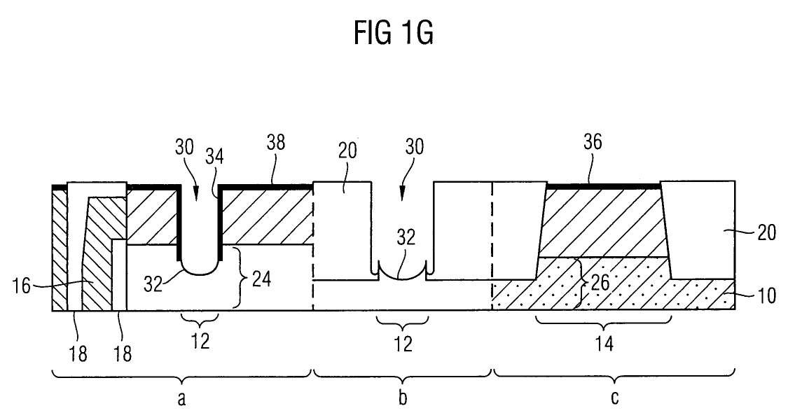

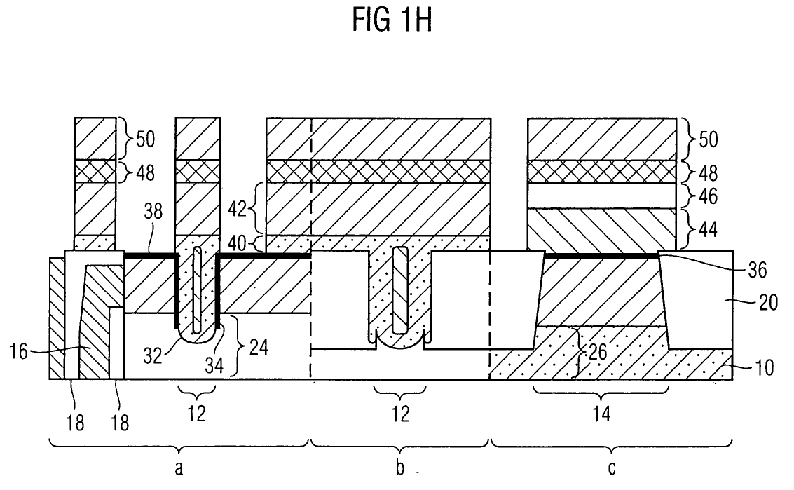

FIG. 1A to 1H show cross sections of a semiconductor substrate for illustrating a first embodiment of the method of manufacturing an integrated circuit; namely a) as a cross section of an array perpendicular to a wordline to be formed; b) as a cross section of said array parallel to the wordline to be formed; and c) as a cross section of a support separated from said array.

In a first process step of the method, a semiconductor substrate 10, for instance comprising silicon, is provided. Said semiconductor substrate 10 comprises a plurality of regions 12 where recessed channel transistors shall be formed. The semiconductor substrate 10 also comprises a plurality of regions 14 where planar transistors shall be formed. Said recessed channel transistors and said planar transistors can be components of a DRAM. However, the present invention is not restricted to the fabrication of a DRAM.

The reference number 16 denotes a buried strap which is formed near to the region 12. Said buried strap 16 has an insulation 18, for instance made of an oxide. Methods of forming such a buried strap 16 with an insulation 18 are known from the prior art. However, the present invention is not restricted to an array in contact with such a buried strap 16.

As can be seen from FIG. 1A, insulation trenches 20 are etched into the surface of the semiconductor substrate 10. The insulation trenches 20 are filled with an insulating material, for example with silicon oxide. Of course, various other insulating materials could also be filled into the insulation trenches 20.

A sacrificial oxide layer 22 is formed on the surface of the semiconductor substrate 10. In case that the semiconductor substrate 10 consists of silicon, said sacrificial oxide layer 22 can be formed during a thermal oxidation step.

Subsequently, various ion implantation steps can be performed to form different wells 24 and 26. These wells can be n-doped or p-doped or not doped. In the present embodiment, the wells 24 and 26 are formed for the recessed channel transistor and the planar transistor later to be formed. However, the wells 24 and 26 are not needed for the process steps described in more detail here.

Optional, a rapid thermal processing (RTP) anneal is performed for the well diffusion. The result is shown in FIG. 1B.

In a following process step shown in FIG. 1C, a mask 28, for instance a carbon hard mask (CHM) or a photoresist mask, is deposited on the surface of the semiconductor substrate 10.

In a following lithographic step, the mask 28 is patterned. An etching step is performed to remove the areas of the mask 28 above the regions 12. The areas of mask 28 covering the regions 14 are not removed during the etching step.

Afterwards, an etching step is performed to etch a plurality of trenches 30 into the unprotected regions 12. Said etching step can be selective or unselective to oxide. For instance, said etching step can be a reactive ion etch (RIE) step or a chemical downstream etch (CDE) step.

The result of said etching step is shown in FIG. 1D. The trench 30 has a vertical centre plane 31 which is perpendicular to the surface of the semiconductor substrate 10 and to the cross-section of FIG. 1A to 1H. For example, the trench 30 can have a width between 20 nm to 100 nm. The depth can be in a range between 50 nm to 400 nm. However, the inventive method is not restricted to a trench 30 with a special size.

In the example of FIG. 1D, the trench 30 has a width limited by the distance between two adjacent insulating trenches 20 and/or the etched hole within the mask 28. In the present example, the RIE step or the CDE step is selective to the oxide filling of the insulation trenches 20, while removing the silicon between the two adjacent insulation trenches 20 of the array. Also, after said RIE step or said CDE step, the bottom of the trench 30 may have rounded corners.

During the etching steps explained above, the sacrificial oxide layer 22 is protected above the regions 14 by the mask 28. Therefore, it is not removed from the regions 14 during these etching steps.

In a following process step, the mask 28 is removed from the surface of the semiconductor substrate 10. The result is shown in FIG. 1D.

Then, as shown in FIG. 1E, an ion implantation step is performed. The direction of said ion implantation is parallel to the vertical centre plane 31 of the trench 30. An implant species of said ion implantation can comprise for instance nitrogen. Thus, an ion implant is introduced near to the surface of the bottom of the trench 30. Optionally, a recessed channel LCI (local channel implant) can be carried out.

There are two options in view of region 14. In a first case, region 14 is covered during said ion implantation step by a layer which is thick enough to inhibit the introduction of an ion implant into region 14. Otherwise, an ion implant is also introduced near to the surface of region 14.

The ion implantation slightly damages the sidewalls of the trench 30. However, there is not significant ion implant near to the sidewalls of the trench 30.

Subsequently, the damaged sacrificial oxide layer 22 is removed from the surface of the semiconductor substrate 10. The damaged sidewalls of the trenches 30 are also removed, forming pockets 37 in the oxide filling of the insulation trenches 20 exposing a sidewall portion of the silicon at the bottom of trench 30, as can be seen from FIG. 1F. However, the present invention is not restricted to a special shape of trench 30.

After the removal of the damaged oxide areas, a single oxidation step is carried out to form a first oxide layer 32 covering the bottom of the trench 30, a second oxide layer 34 covering the sidewalls of the trench 30 and a third oxide layer 36 covering the region 14. The result is shown in FIG. 1F.

All three oxide layers 32, 34 and 36 are formed in a single oxidation step. This oxidation step is for instance a thermal oxidation step. The oxidation step does not comprise an etching step.

The first oxide layer 32 is formed in contact with the ion implant near to the surface of the bottom of the trench 30. The second oxide layer 34 is formed distant from said ion implant.

Due to the ion implant, the first oxide layer 32 at the bottom of the trench 30 has a layer thickness that is significantly smaller than the layer thicknesses of the second oxide layer 34 covering the walls of the trench 30. Also, the layer thickness of the first oxide layer 32 may be significantly smaller than the layer thickness of the third oxide layer 36, in case that there is not ion implant near to the surface of region 14.

In a further embodiment, there is an ion implant near to the surface of region 14; the layer thickness of the third oxide layer 36 can be in the range of the layer thickness of the first oxide layer 32.

It is also possible to tailor the implant dose near to the surface of region 14 in order to define the thickness of the third oxide layer 36 relative to the thickness of layer 32.

It is further possible, to cover region 14 with a thin layer during the ion implantation step, so that the ion implant near to the surface of region 14 has a lower concentration than the ion implant near to the bottom of trench 30. Then, the layer thickness of the third oxide layer 36 may be larger than the layer thickness of the first oxide layer 32, but smaller than the layer thickness of the second oxide layer 34.

In a broader aspect of this invention, it is possible to form oxide layers 32, 34 and 36 with different layer thicknesses by one single oxidation step. Therefore, it is not necessary to perform different oxidation steps for the formation of oxide layers 32, 34 and 36 with different layer thicknesses. It is also not necessary to use a mask during an oxidation step or to reduce the layer thickness of one of the oxide layers 32, 34 or 36 by an etching step.

For instance, the first oxide layer 32 has a layer thickness in a range between 3 to 8 nm. The second oxide layer 34 and the third oxide layer 36 may have layer thicknesses which are significantly larger, for example in a range between 10 to 20 nm. However, the present invention is not restricted to this example.

During the same oxidation step, an additional oxide layer 38 can be formed on the surface of the semiconductor substrate 10 surrounding the trench 30. The layer thickness of said additional oxide layer 38 may be in the range of the layer thicknesses of the first oxide layer 32, in case that there is an ion implant near to the additional oxide layer 38, or in the range of the layer thicknesses of the second oxide layer 34, in case that there is no ion implant near to the additional oxide layer 38.

After the formation of the oxide layers 32, 34, 36 and 38, a polysilicon deposition is carried out. Then, different regions 40, 42, 44 and 46 are doped to have different doping concentrations. For example, region 40 may be highly doped with phosphor, region 42 may not be doped and region 44 may comprise an opposite doping to region 40. Of course, the present invention is not limited to the given example of the doping concentrations of the regions 40 to 46.

Afterwards, an additional layer 48 of tungsten may be deposited on the layers 40 to 46. Then, an upper layer 50, for instance consisting of silicon nitride, is formed on layer 48 and planarized. In a final process step, a stack structuring is carried out. The result is shown in FIG. 1H.

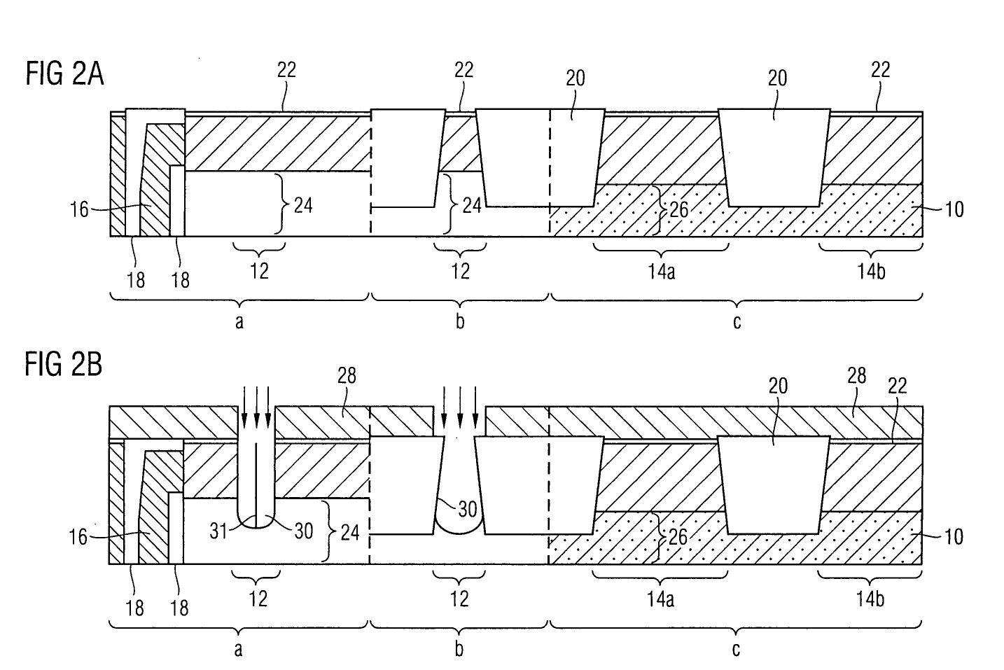

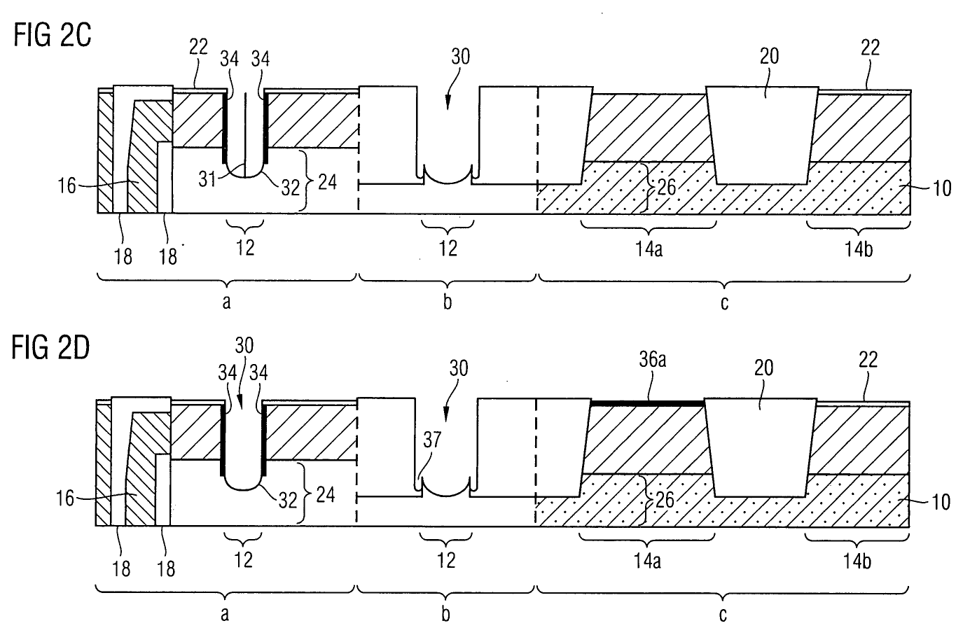

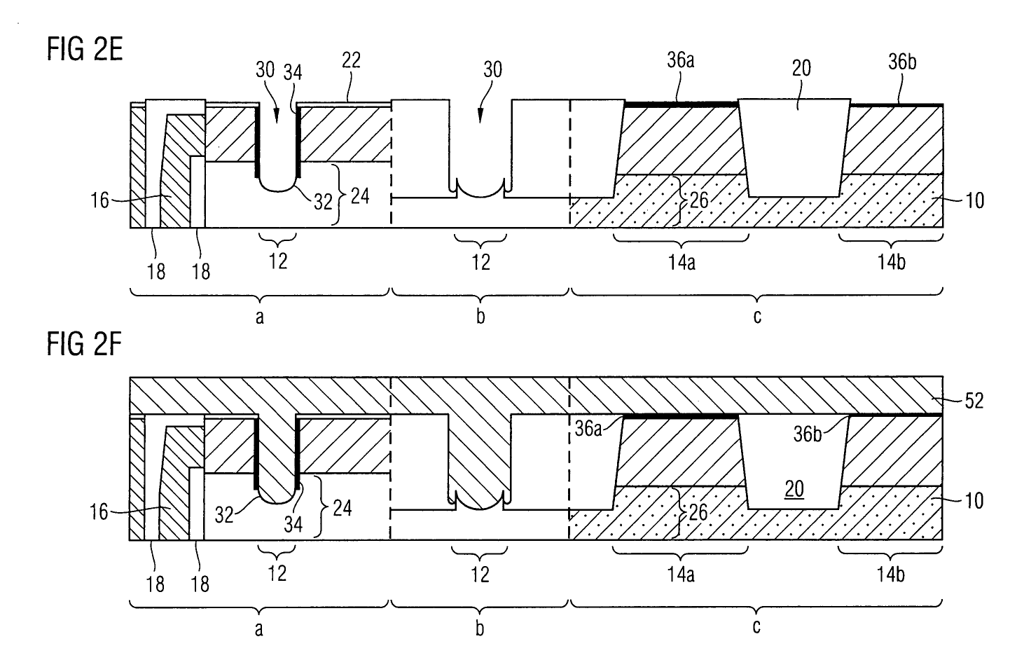

FIG. 2A to 2F show cross sections of a semiconductor substrate for illustrating a second embodiment of the method of manufacturing an integrated circuit; namely a) as a cross section of an array perpendicular to a wordline to be formed; b) as a cross section of said array parallel to the wordline to be formed; and c) as a cross section of a support separated from said array.

FIG. 2A is almost identical with FIG. 1B. They show a semiconductor substrate 10 with a plurality of regions 12 for a later to be formed recessed channel transistor, adjacent buried straps 16 with insulations 18 and insulating trenches 20 filled with an insulating material. In opposite to FIG. 1B, the semiconductor substrate 10 comprises a plurality of regions 14a and 14b to build a pFET (regions 14a) and an nFET (regions 14b). However, the present embodiment is not restricted to a method of fabricating a pFET and/or a nFET.

A sacrificial oxide layer 22 is formed on the surface of the semiconductor substrate 10. Said sacrificial oxide layer 22 covers the surface of all the regions 12, 14a and 14b. The semiconductor substrate 10 can also comprise wells 24 and 26. However, the method explained in more detail below is not restricted to a special type of doping of the wells 24 and 26.

In a subsequent process step shown in FIG. 2B, a mask 28, for example a carbon hard mask, is deposited on the surface of the semiconductor substrate 10. Said mask is exposed above the regions 12. Then, the exposed areas of the mask 28 are etched. This is done in an etching step which is selective to the exposed areas of the mask 28.

Afterwards, a trench 30 is etched into the unprotected region 12. This is done in a RIE step or a CDE step which is selective or unselective to oxide. The trench 30 has a vertical centre plane 31 which is perpendicular to the surface of the semiconductor substrate 10. For example, the newly formed trench 30 has a width in a range between 20 nm to 100 nm and a depth in a range between 50 nm to 400 nm. The bottom of the trench 30 may have rounded corners. However, the present invention is not restricted to a special shape of the bottom of trench 30.

During said RIE step or said CDE step, the sacrificial oxide layer 22 covering the regions 14a and 14b is protected by the mask 28.

The mask 28 also protects the regions 14a and 14b during the subsequent ion implantation step. An example for an implant species of said ion implantation is nitrogen. The direction of said ion implantation step is parallel to the vertical centre plane 31 of trench 30 and perpendicular to the surface of the semiconductor substrate 10. Thus, an ion implant is introduced near to the surface of the bottom of said trench 30.

In a following process step, the mask 28 is removed from the surface of the semiconductor substrate 10.

Then, a first thermal oxidation process is carried out to form the oxide layers 32 and 34 in the trench 30. Oxide layer 32 is formed at the bottom of trench 30. The sidewalls of trench 30 are covered by oxide layer 34. Thus, oxide layer 32 is formed in contact with the ion implant at the bottom of trench 30 while oxide layer 34 is separated from said ion implant. Therefore, the oxide layers 32 and 34 have different layer thicknesses.

As can be seen from FIG. 2C, the oxide layer 32 formed near to the bottom of said trench 30 is significantly thinner than the oxide layer 34 covering the sidewalls of trench 30. For instance, the oxide layer 32 formed near to the bottom of trench 30 has a layer thickness in a range between 2 nm to 8 nm and the oxide layer 34 covering the sidewalls of trench 30 has a layer thickness in a range between 8 nm to 20 nm.

However, the present invention is not restricted to this example. The layer thicknesses of the oxide layers 32 and 34 depend on the duration of said first thermal oxide process and on the amount of the ion implant near to the bottom of trench 30. Therefore, it is possible to differ the ranges of the layer thicknesses of the oxide layers 32 and 34.

The layer thickness of the sacrificial oxide layer 22 covering the regions 14a and 14b and the surrounding of the trench 30 may also be increased during this first thermal oxidation process.

In a subsequent process step, the sacrificial oxide layer 22 is removed from the region 14b. The result is shown in the FIG. 2C.

A second thermal oxidation process is then carried out to form an oxide layer 36a on the region 14a. The layer thickness of said new oxide layer 36a on region 14a may be in a range between 2 nm to 8 nm, for example.

Then, the sacrificial oxide layer 22 on the region 14b is etched away. In a third thermal oxidation step, an oxide layer 36b is formed on the region 14b. In the present example, the duration of the third thermal oxidation step is chosen short enough to provide an oxide layer 36b covering the region 14b which is significantly thinner than the oxide layer 36a covering the region 14a. The layer thickness of the oxide layer 36a covering the region 16a may be increased during said third thermal oxidation step, as can be seen from FIG. 2E.

Thus, it is possible to form oxide layers 36a and 36b with different layer thicknesses on the regions 14a and 14b. For instance, it is possible to form oxide layers 36a and 36b with different layer thicknesses for a pFET and an nFET. Compared to methods known from the prior art, the method explained above can be carried out relatively easy.

Finally, a polysilicon layer 52 is formed and planarized on the semiconductor substrate 10. The result is shown in FIG. 2F.

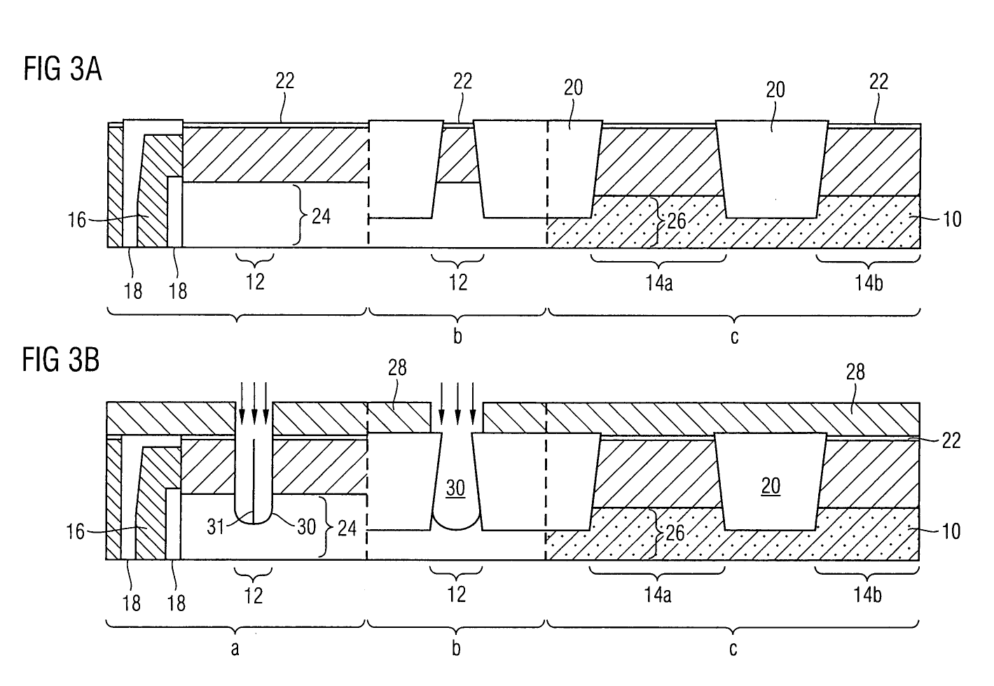

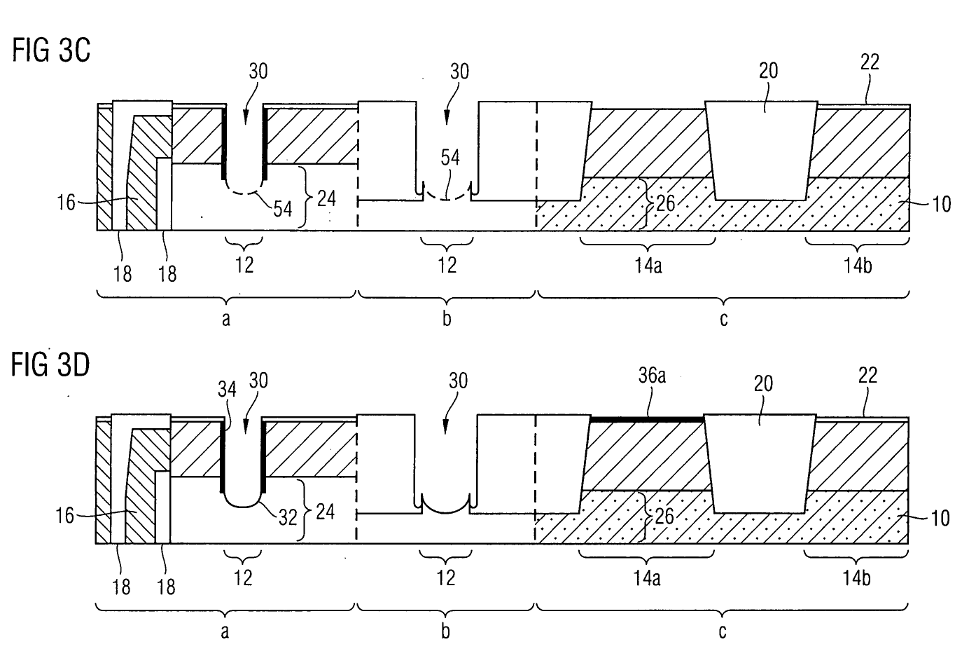

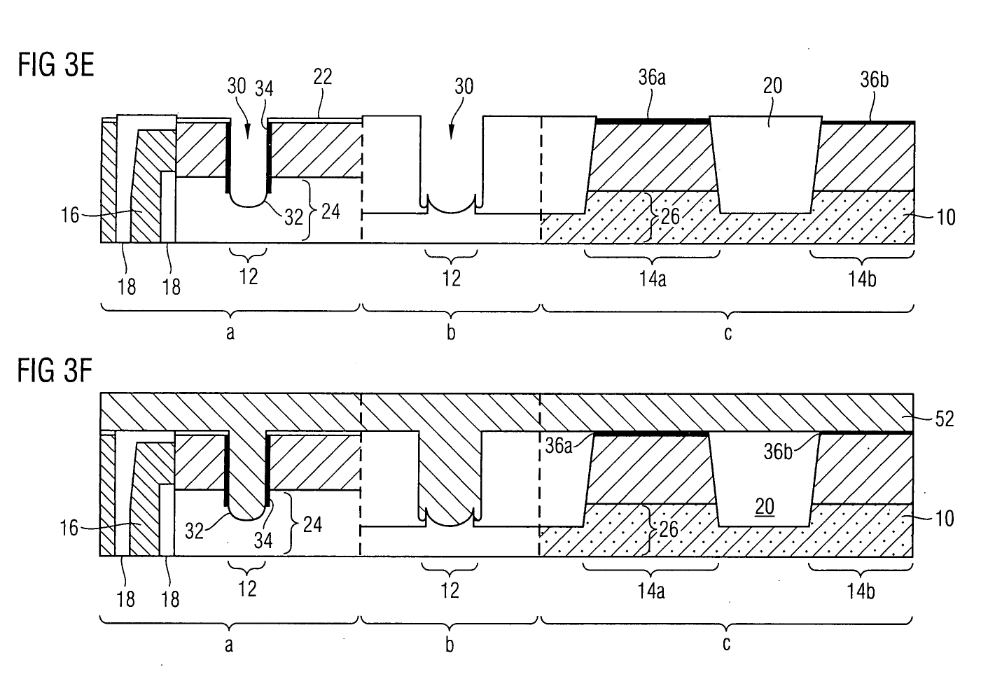

FIG. 3A to 3F show cross sections of a semiconductor substrate for illustrating a third embodiment of the method of manufacturing an integrated circuit; namely a) as a cross section of an array perpendicular to a wordline to be formed; b) as a cross section of said array parallel to the wordline to be formed; and c) as a cross section of a support separated from said array.

FIG. 3A is identical with FIG. 2A. Therefore, it is not explained in more detail here.

In a following process step, a mask 28, for example a carbon hard mask, is deposited on the surface of the semiconductor substrate 10. Said mask 28 is structured according to the method described above.

Then, a RIE step or a CDE step is performed to etch a trench 30 into region 12. The newly etched trench 30 has a vertical centre plane 31 which is perpendicular to the surface of the semiconductor substrate 10.

In a subsequent process step, an ion implantation step is performed. An implant species of said ion implantation step can be for instance nitrogen. The direction of said ion implantation is parallel to the vertical centre plane 31 of the trench 30, as can be seen in the FIG. 3B. Thus, an ion implant is deposited near to the surface of the bottom of said trench 30. Said ion implant serves to vary the layer thicknesses of oxide layers 32 and 34 formed in said trench 30 in a following process step.

Then, the mask 28 is removed completely. Subsequently, a first thermal oxidation step is carried out to form the oxide layers 32 and 34 in the trench 30. These newly formed oxide layers 32 and 34 have different layer thicknesses in the implanted and the non-implanted portions. Because of said ion doping near to the bottom of trench 30, the oxide layer 32 formed near to the bottom of said trench 30 is significantly thinner than the oxide layer 34 covering the sidewalls of trench 30.

An anisotropic dry etch step is then performed to etch the newly formed oxide layer 32 near to the bottom of trench 30 and the sacrificial oxide layer 22 covering the region 14a. The result is shown in the FIG. 3C. The broken lines 54 show the side of the removed oxide layer 32 of trench 30.

Of course, it is also possible to perform more than one etching steps to remove the oxide layer 32 near to the bottom of trench 30 and the sacrificial oxide layer 22 covering the region 14a. For example, in a first etching step only the oxide layer 32 near to the bottom of trench 30 is removed. Then, in an additional etching step, for example a wet etching step, the sacrificial oxide layer 22 covering the region 14a is etched.

FIG. 3D show the second thermal oxidation process, carried out to form a new oxide layer 32 at the bottom of trench 30 and a new oxide layer 36a covering the region 14a. The different layer thicknesses of the oxide layers 32 and 34 of trench 30 are shown in the FIG. 3D.

Then, the sacrificial oxide layer 22 is removed from the region 14b, while the oxide layers 32, 34 and 36a are protected by a mask. Said mask is removed from the semiconductor substrate 10. Afterwards, a third thermal oxidation step is performed to form a new oxide layer 36b on the region 14b. Said new oxide layer 36b is significantly thinner than the oxide layer 36a on region 14a.

The result is shown in the FIG. 3E. Due to the ion doping near to the surface of the bottom of the trench 30, the oxide layer 32 at the bottom of the trench 30 is significantly thinner than the oxide layer 34 covering the sidewalls of said trench 30. Also, the newly formed oxide layer 36b covering the region 14b is significantly thinner than the oxide layer 36a on the region 14a.

Finally, as shown in the FIG. 3F, a polysilicon layer 52 is deposited in a single poly deposition step.

The following process steps carried out to produce an integrated circuit comprising a recessed channel transistor, a pFET and an nFET are known from the prior art. Therefore, they are not explained here.

What is claimed is:

1. Method of manufacturing an integrated circuit comprising the steps of:
providing a semiconductor substrate;
etching at least one trench into a surface of said semiconductor substrate;
performing an ion implantation step, wherein a direction of said ion implantation step is parallel to a vertical centre line of said trench; and
performing a single oxidation step to form a first oxide layer with a first layer thickness covering a bottom of said at least one trench and a second oxide layer with a second layer thickness covering the sidewalls of said at least one trench, wherein said first layer thickness differs from said second layer thickness.

2. Method of claim 1, wherein said first layer thickness is smaller than said second layer thickness.

3. Method of claim 1, wherein an implant species of said ion implantation step comprises Nitrogen.

4. Method of claim 1, wherein said semiconductor substrate comprises silicon.

5. Method of claim 4, wherein said single oxidation step comprises a thermal oxidation step.

6. Method of claim 1, wherein said step of etching said at least one trench comprises a reactive ion etch (RIE) step.

7. Method of claim 1, wherein said step of etching said at least one trench comprises a chemical downstream etch (CDE) step.

8. Method of claim 1, wherein the first layer thickness of said first oxide layer is in a range between 3 to 8 nm and the second layer thickness of said second oxide layer is in a range between 7 to 20 nm.

9. Method of claim 1, wherein another ion implantation step is performed to form doped regions within said semiconductor substrate.

10. Method of claim 9, wherein the oxide layers form gate oxides of transistors.

11. Method of claim 9, wherein at least one recessed channel transistor is formed in said at least one trench.

12. Method of claim 1, further comprising the steps of
covering a plurality of regions of said semiconductor substrate with at least one layer before the ion implantation step;
removing said at least one layer of said regions after the ion implantation step; and
forming a third oxide layer with a third layer thickness covering said regions by the single oxidation step.

13. Method of claim 12, wherein said third layer thickness equals said second layer thickness.

14. Method of claim 12, wherein said at least one layer comprises an oxide layer.

15. Method of claim 12, wherein said at least one layer comprises a carbon hard mask (CHM).

16. Method of claim 12, wherein a plurality of planar transistors is formed on said regions.

17. Method of claim 1, further comprising the steps of:
covering a first and a second plurality of regions of said semiconductor substrate with at least one layer before the ion implantation step;
removing said at least one layer of said first plurality of regions after the ion implantation step;
forming a third oxide layer with a third layer thickness covering said first plurality of regions by said single oxidation step;
removing said at least one layer of said second plurality of regions; and
performing a second oxidation step to form a forth oxide layer on said second plurality of regions.

18. Method of claim 17, wherein said third layer thickness is increased by said second oxidation step.

19. Method of claim 17, wherein said second oxidation step comprises a thermal oxidation step.

20. Method of claim 17, wherein a plurality of PFET is formed on said first plurality of regions and plurality of nFET is formed on said second plurality of regions.

21. Method of claim 1, wherein a memory device is formed on said semiconductor substrate.

22. Method of claim 1, wherein a DRAM (Dynamic Random Access Memory) is formed on said semiconductor substrate.
